(19) United States
(12) Patent Application Publication
(10) Pub. No.: US 2010/0207231 A1
(43) Pub. Date: Aug. 19, 2010

(54) SOLID-STATE IMAGE DEVICE AND METHOD OF MANUFACTURING THE SAME

(75) Inventors: Masatoshi IWAMOTO, Kyoto (JP); Tohru YAMADA, Kyoto (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/706,249

(22) Filed: Feb. 16, 2010

(30) Foreign Application Priority Data
Feb. 16, 2009 (JP) 2009-032103

(51) Int. Cl. H01L 31/103; H01L 31/18

(52) U.S. Cl. 257/461; 438/57; 257/E31.057

(57) ABSTRACT

Photoelectric conversion regions (130, 140) are formed from both sides of a semiconductor substrate 100, so that the photoelectric conversion regions (130, 140) can be easily formed at a deep position from the surfaces of the semiconductor substrate 100 without using a high-energy ion implanter and a thick resist. With this configuration, long-wavelength input light from a visible light region to a far-red light region can be efficiently absorbed from the outside. Thus it is possible to improve the light receiving sensitivity of a solid-state image device and increase the number of pixels of the solid-state image device without reducing sensitivity in a unit pixel.

### FIELD OF THE INVENTION

The present invention relates to a solid-state image device for obtaining an image by photoelectrically converting incident light and a method of manufacturing the same, and particularly relates to a backside-illumination solid-state image device having a signal reading surface and a light receiving surface placed on opposite sides and a method of manufacturing the same.

### BACKGROUND OF THE INVENTION

In recent years, digital cameras have been widely used and higher image quality with enhanced definition has been demanded. In order to improve image quality and so on, the number of pixels has been increased in solid-state image devices mounted in digital cameras. For example, the number of pixels can be increased by reducing the unit pixel of a solid-state image device. However, as the unit pixel is reduced, an amount of light received from the outside decreases accordingly, so that sensitivity in the unit pixel disadvantageously declines.

Thus in order to improve the sensitivity of a light receiving part and prevent a reduction in sensitivity in a unit pixel, a technique of a backside-illumination solid-state image device has been proposed in which a carrier generated by converting incident light on the back side of a substrate is guided to the front side to read a signal. Since a signal reading surface and a light receiving surface are placed on opposite sides, the light receiving surface can be so large as to prevent a reduction in sensitivity in the unit pixel.

Referring to FIG. 5, a solid-state image device of the prior art will be described below.

FIG. 5 is a sectional view showing the configuration of the solid-state image device of the prior art.

As an example of the backside-illumination solid-state image device of the prior art, FIG. 5 shows a method in which photoelectric conversion regions 330 are formed by generating impurity concentration gradients in the photoelectric conversion region. By changing the impurity concentration gradients of the photoelectric conversion region from n− to n+ from the back side of a semiconductor substrate, the potential gradients are generated in the depth direction (for example, see US 2006/43519).

### DISCLOSURE OF THE INVENTION

In the solid-state image device of the prior art, however, the photoelectric conversion regions 330 are formed by using an ion implanter from one side of the semiconductor substrate 300.

Thus in the solid-state image device manufactured by the foregoing manufacturing method, the photoelectric conversion regions cannot be formed to a sufficient depth. The implantation of impurities expands toward the other side of the semiconductor substrate 300, so that the photoelectric conversion regions can be formed only with a depth of about 3 μm in order to keep precise implantation in impurities regions. For this reason, sensitivity considerably declines in long-wavelength light photoelectrically converted mainly in a deep region.

Further, when impurities are implanted with a sufficient depth, the impurities are diffused in a deep region, so that the impurity regions cannot be accurately formed.

Moreover, the implantation of impurities with a sufficient depth requires a thick resist treatable with an aspect ratio of at least 10 and an ion implanter of high energy.

The thick resist and the ion implanter for a mass production technique are quite expensive to develop, thereby increasing the cost of the manufacturing process.

Moreover, a high-energy ion implantation process is performed from the front side of the semiconductor substrate 300 which receives input light. Thus it is difficult to set the conditions of a process of annealing and the like for reducing generated crystal defects and the like after the implantation, or the cost disadvantageously increases.

Further, in the photoelectric conversion region 330 disposed on the back side of the semiconductor substrate 300, the impurity concentration gradient is formed such that the concentration of the photoelectric conversion region 330 is increased from the back side to the front side of the semiconductor substrate 300. Thus the sensitivity declines on the short wavelength side.

The present invention has been devised to solve the foregoing problems. An object of the present invention is to provide a backside-illumination solid-state image device which can inexpensively form a charge storage layer at a deep position of a semiconductor substrate and suppress a reduction in sensitivity even in a long-wavelength region without using a thick resist treatable with a high aspect ratio and a special high-energy ion implanter.

In other words, an object of the present invention is to easily suppress a reduction in sensitivity even in a long-wavelength region while increasing the number of pixels.

In order to attain the object, a solid-state image device of the present invention for obtaining an image by photoelectrically converting incident light in a light receiving part formed on a semiconductor substrate, the light receiving part including: a first semiconductor well of first conductivity type formed on the opposite side of the semiconductor substrate from an incident light receiving surface; a second semiconductor well of the first conductivity type formed on a surface on the incident light receiving surface of the semiconductor substrate; a charge storage region of second conductivity type formed between the first semiconductor well of the first conductivity type and the second semiconductor well of the first conductivity type, next to the first semiconductor well of the first conductivity type; and a photoelectric conversion region formed next to the second semiconductor well of the first conductivity type and the charge storage region of the second conductivity type, wherein the photoelectric conversion region is made up of a first photoelectric conversion region of the second conductivity type and a second photoelectric conversion region of the second conductivity type, and the photoelectric conversion region has a depth that enables photoelectric conversion of at least a half of incident light having the maximum wavelength in incident visible light, the depth being equivalent to a distance between the second semiconductor well of the first conductivity type and the charge storage region of the second conductivity type of the photoelectric conversion region.

Further, it is preferable that the photoelectric conversion region is at least 6 m in depth.

Moreover, it is preferable that the first photoelectric conversion region of the second conductivity type has a lower impurity concentration than the second photoelectric conversion region of the second conductivity type.

Further, it is preferable that the second photoelectric conversion region of the second conductivity type has a larger implantation cross sectional area than the first photoelectric conversion region of the second conductivity type.

A method of manufacturing a solid-state image device according to the present invention, when forming the light receiving part of the solid-state image device, the method including the steps of: forming the first semiconductor well of the first conductivity type, the charge storage region of the second conductivity type, and the first photoelectric conversion region of the second conductivity type in the semiconductor substrate of the first conductivity type by ion implantation from a surface of an opposite side of the semiconductor substrate from the incident light receiving surface; and forming the second photoelectric conversion region of the second conductivity type and the second semiconductor well of the first conductivity type in the semiconductor substrate of the first conductivity type by ion implantation from the surface on the incident light receiving surface.

### BRIEF DESCRIPTION OF THE DRAWINGS

FIG. 1A is an explanatory drawing showing the configuration of a solid-state image device according to a first embodiment;

FIG. 1B is an explanatory drawing showing the configuration of the solid-state image device according to the first embodiment;

FIG. 2A is a process sectional view showing a method of manufacturing the solid-state image device of the present invention;

FIG. 2B is a process sectional view showing the method of manufacturing the solid-state image device of the present invention;

FIG. 2C is a process sectional view showing the method of manufacturing the solid-state image device of the present invention;

FIG. 2D is a process sectional view showing the method of manufacturing the solid-state image device of the present invention;

FIG. 2E is a process sectional view showing the method of manufacturing the solid-state image device of the present invention;

FIG. 3A is an explanatory drawing showing a solid-state image device according to a second embodiment;

FIG. 3B is an explanatory drawing showing the solid-state image device according to the second embodiment;

FIG. 4A is an explanatory drawing showing a solid-state image device according to a third embodiment;

FIG. 4B is an explanatory drawing showing the solid-state image device according to the third embodiment; and

FIG. 5 is an explanatory drawing showing a solid-state image device of the prior art.

### DESCRIPTION OF THE EMBODIMENTS

### First Embodiment

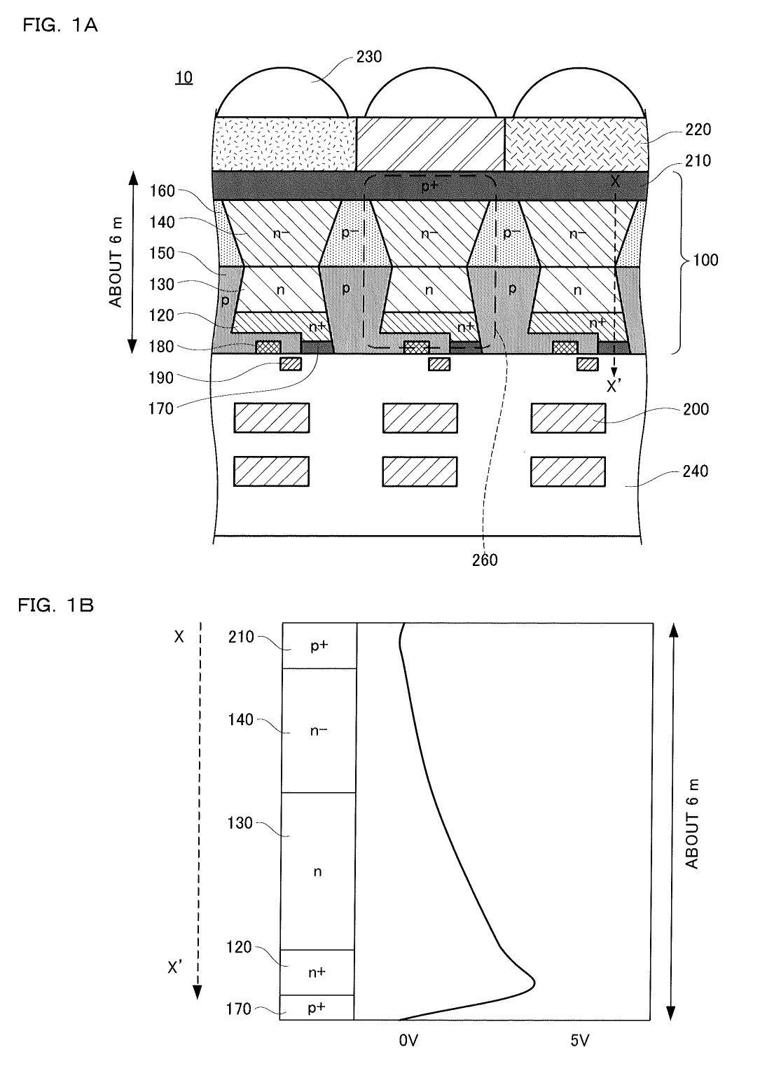

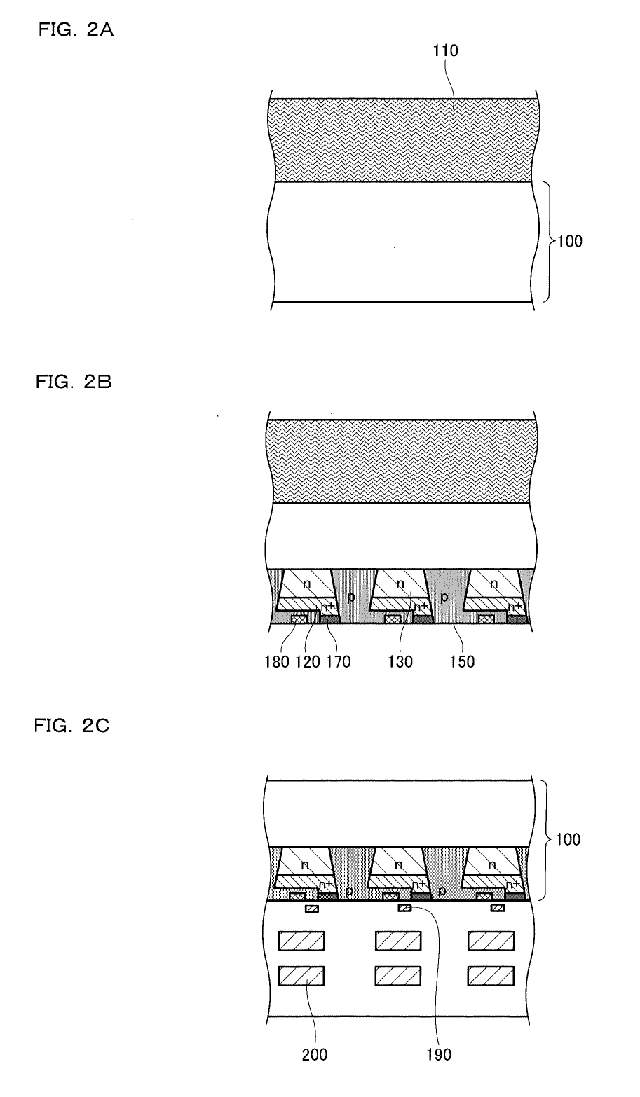

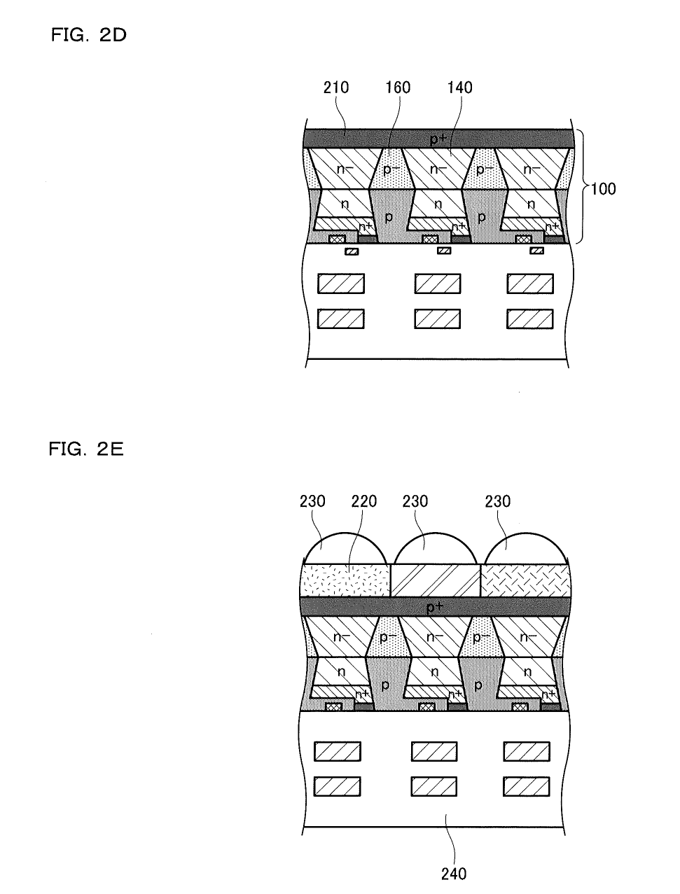

Referring to FIGS. 1A, 1B, and 2A to 2E, a solid-state image device and a method of manufacturing the same according to a first embodiment will be first described below.

FIGS. 1A and 1B are explanatory drawings showing the solid-state image device according to the first embodiment. FIG. 1A is a sectional view showing the configuration of the solid-state image device according to the first embodiment and FIG. 1B shows a potential profile in cross section taken along line X-X′ of FIG. 1A. FIGS. 2A to 2E are process sectional views showing a method of manufacturing the solid-state image device of the present invention.

As shown in FIG. 1A, a backside-illumination solid-state image device 10 according to the first embodiment includes light receiving parts 260 formed in a p-type semiconductor substrate 100. The light receiving part 260 includes a charge storage region 120, a first n-type photoelectric conversion region 130 and a second n-type photoelectric conversion region 140 which serve as a photoelectric conversion region, and a first p-type semiconductor well 170 for suppressing the occurrence of dark current with a high impurity concentration. Further, a p-type device isolation region for determining each unit pixel region is formed of a first p-type device isolation region 150 and a second p-type device isolation region 160. The first p-type device isolation region 150 and the second p-type device isolation region 160 have a concentration distribution in which an impurity concentration gradually increases from a low concentration p− from the back side serving as the light incidence side of the semiconductor substrate 100 up to a high concentration p+ toward the front side of the semiconductor substrate 100. Moreover, in an insulating film layer 240 formed next to the front side of the semiconductor substrate, a plurality of wiring layers 200 are disposed and MOS transistors (not shown) are formed for reading signal charge stored after photoelectric conversion.

Referring to FIGS. 2A to 2E, the following will specifically describe the method of manufacturing the backside-illumination, solid-state image device according to the first embodiment. First, the semiconductor substrate 100 is grown with a thickness of, for example, about 30 μm on a surface of a substrate member 110 such as a p-type semiconductor substrate. The substrate member 110 may be made of any material (FIG. 2A) as long as epitaxial growth is possible. By using the substrate configured thus (a combined substrate of the substrate member 110 and the semiconductor substrate 100), the charge storage regions 120, FD portions 180, the first n-type photoelectric conversion regions 130 each of which is a part of the photoelectric conversion region, the first p-type device isolation regions 150 each of which is a part of the device isolation region, and the first p-type semiconductor wells 170 are formed by ion implantation on the front side of the semiconductor substrate 100. Acceleration energy during implantation ranges from, for example, about 2 MeV to 5 MeV. At this point, implanted impurities are diffused in a deep region of the first n-type photoelectric conversion region 130 and the first n-type photoelectric conversion region 130 narrows toward the back side of the semiconductor substrate 100 (FIG. 2B). Next, gate electrodes 190 and the wiring layers 200 are formed, and then the substrate is flipped over. Further, the semiconductor substrate 100 is polished to have a thickness of, for example, at least 6 μm by chemical mechanical polishing (CMP), and then the substrate member 110 is removed on the back side serving as a surface for receiving incident light (FIG. 2C). After that, from the back side of the semiconductor substrate 100, the second n-type photoelectric conversion regions 140, the second p-type device isolation regions 160, and a p-type diffusion layer 210 are formed by ion implantation, and then heat treatment using laser annealing and the like is performed at, for example, about 1000° C., so that the impurities formed by ion implantation are activated. At this point, the implanted impurities are diffused in a deep region of the second n-type photoelectric conversion region 140, and the formed second n-type photoelectric conversion region 140 narrows toward the front side of the semiconductor substrate 100. In the first embodiment, the n-type impurity concentration of the second n-type photoelectric conversion region 140 is lower than that of the first n-type photoelectric conversion region 130 (FIG. 2D). At this point, the second n-type photoelectric conversion region 140 is formed so deeply as to connect to the first n-type photoelectric conversion region 130, and the total thickness of the first n-type photoelectric conversion region 130 and the second n-type photoelectric conversion region 140 is not smaller than the depth of a photoelectric conversion region capable of sufficiently absorbing the wavelength of incident light. To be specific, the photoelectric conversion regions 130 and 140 are preferably so deep as to photoelectrically convert at least about 50% of incident light in red light (a wavelength of about 700 nm) having a long wavelength in visible light. More preferably, the photoelectric conversion regions 130 and 140 are so deep as to photoelectrically convert at least about 50% of incident light in far-red light (a wavelength of about 2500 nm).

Most preferably, the photoelectric conversion regions 130 and 140 are so deep as to photoelectrically convert at least about 80% of incident light in far-red light (a wavelength of about 2500 nm). To be specific, the effect of the present application can be achieved by a thickness of at least about 5 μm. More preferably, a thickness of at least about 6 μm can achieve a remarkable effect. Finally, an on-chip color filter 220 and on-chip lenses 230 are formed (FIG. 2E).

As previously mentioned, the second n-type photoelectric conversion region 140 is formed from the back side of the semiconductor substrate so as to be connected to the first n-type photoelectric conversion region 130 formed from the front side of the semiconductor substrate, so that the first n-type photoelectric conversion region 130 and the second n-type photoelectric conversion region 140 can be formed as a photoelectric conversion region reaching a deep position from the front side of the semiconductor substrate 100, by a simple method without using a high-energy ion implanter or a thick resist. With this configuration, as shown in FIG. 1B, a region having a sufficient potential can be formed to a deep region in the photoelectric conversion region, a gentle gradient can be formed from the second n-type photoelectric conversion region 140 to the charge storage region 120, the charge storage region 120 acts as an overflow barrier region, and the first n-type photoelectric conversion region 130 and the second n-type photoelectric conversion region 140 can efficiently absorb incident light from a visible light region to a far-red light region. Thus it is possible to improve light receiving sensitivity and simultaneously suppress a reduction in sensitivity in a reduced unit pixel.

According to the method of manufacturing the solid-state image device according to the present invention, the device isolation region for electrically isolating the adjacent photoelectric conversion regions can be formed to a depth near the back side of the semiconductor substrate. Thus the photoelectric conversion regions can be expanded to improve sensitivity in the unit pixel, and the satisfactory solid-state image device can be manufactured without reducing sensitivity even when the number of pixels is increased.

Moreover, implanted ions are not passed through a path until input light reaches the photoelectric conversion region in the manufacturing method, so that the input light efficiently reaches the photoelectric conversion region and is absorbed therein without being absorbed by crystal defects generated by ion implantation. Thus it is possible to suppress variations in the sensitivity of the solid-state image device and improve the sensitivity.

The following will describe second and third embodiments of the other backside-illumination solid-state image devices manufactured by the method of manufacturing the backside-illumination solid-state image device according to the first embodiment.

### Second Embodiment

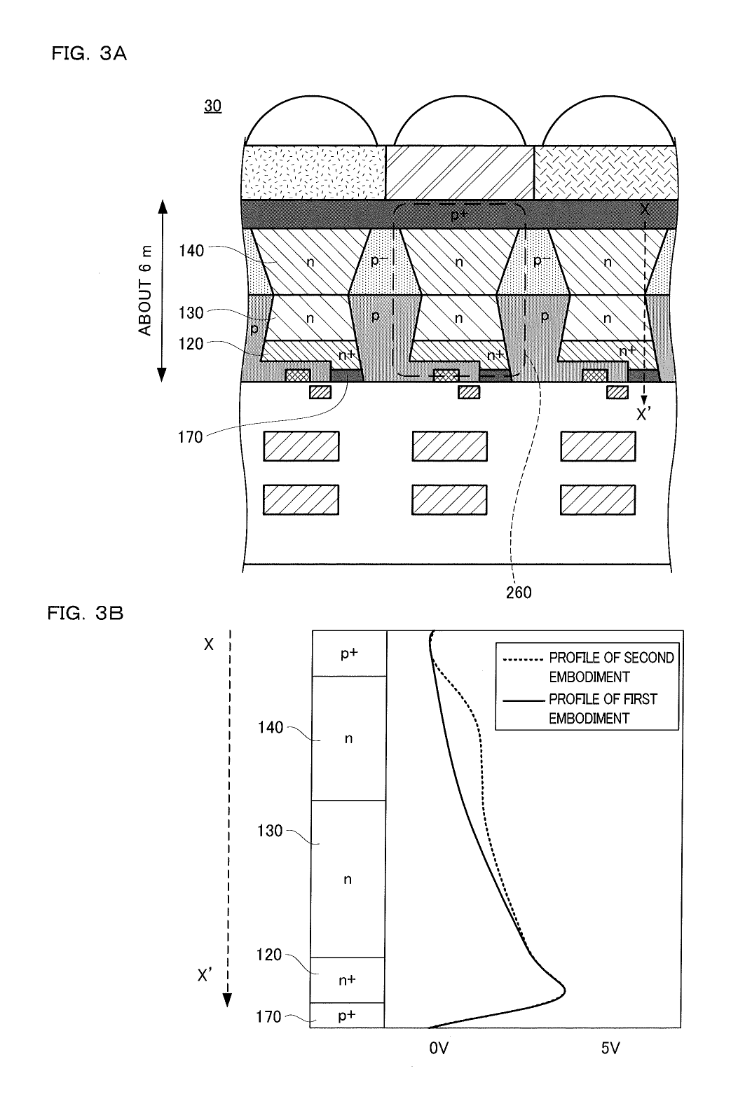

FIGS. 3A and 3B are explanatory drawings showing a solid-state image device according to a second embodiment. FIG. 3A is a sectional view showing the configuration of the solid-state image device according to the second embodiment and FIG. 3B shows a potential profile in cross section taken along line X-X′ of FIG. 3A.

As shown in FIG. 3A, a light receiving part 260 in a backside-illumination solid-state image device 30 of the second embodiment includes a first p-type semiconductor well 170 serving as a positive charge storage region, a charge storage region 120, a first n-type photoelectric conversion region 130, and a second n-type photoelectric conversion region 140. Further, the n-type impurity concentration of the second n-type photoelectric conversion region 140 is close to that of the first n-type photoelectric conversion region 130. The solid-state image device 30 of the second embodiment is different from the backside-illumination solid-state image device 10 of the first embodiment in that a difference in impurity concentration is reduced.

In this way, the n-type impurity concentration of the second n-type photoelectric conversion region 140 is close to that of the first n-type photoelectric conversion region 130. Thus as shown in FIG. 3B, long-wavelength input light can be efficiently absorbed by forming the photoelectric conversion region to a deep position, and the potential profile of the second n-type photoelectric conversion region 140 can be deeply formed unlike in the solid-state image device of the first embodiment in which the potential gradient gradually changes. Further, the photoelectric conversion region is laterally expanded and the photoelectric conversion region on the short-wavelength side is expanded, thereby further increasing sensitivity on the short-wavelength side and the capacity of a photodiode.

### Third Embodiment

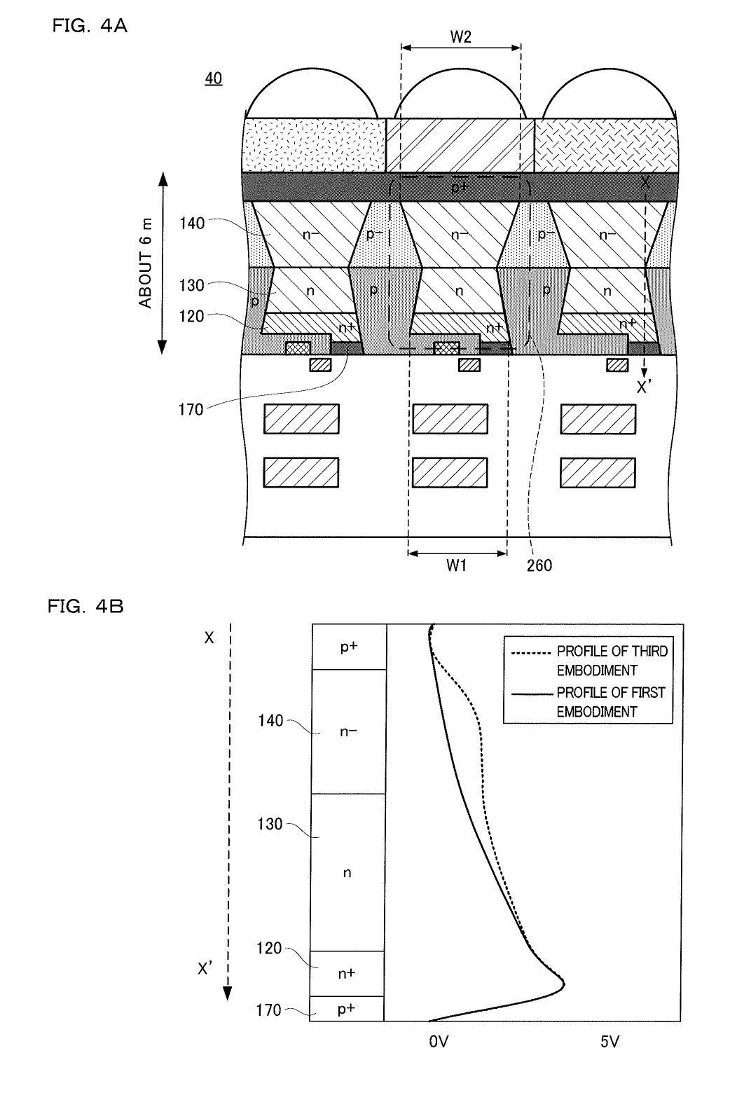

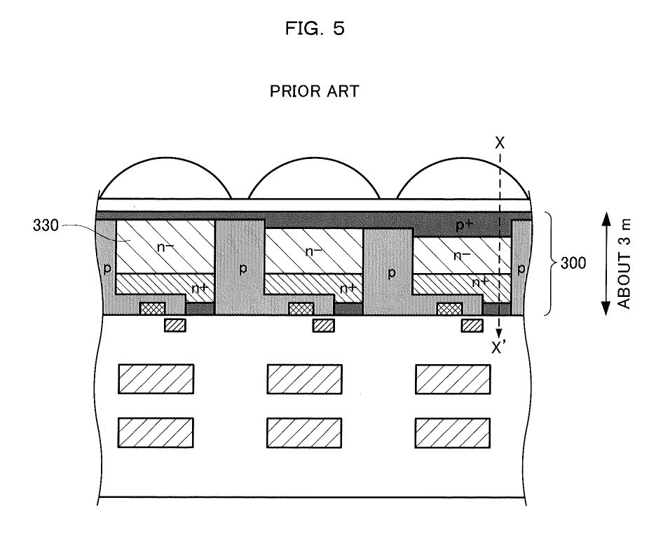

FIGS. 4A and 4B are explanatory drawings showing a solid-state image device according to a third embodiment. FIG. 4A is a sectional view showing the configuration of the solid-state image device according to the third embodiment and FIG. 4B shows a potential profile in cross section taken along line X-X′ of FIG. 4A.

As shown in FIG. 4A, a light receiving part 260 in a solid-state image device 40 of the third embodiment includes a first p-type semiconductor well 170 serving as a positive charge storage region, a charge storage region 120, a first n-type photoelectric conversion region 130, and a second n-type photoelectric conversion region 140. Unlike the solid-state image devices of the first and second embodiments, a feature of the solid-state image device of the present embodiment is that a width W2 of the second n-type photoelectric conversion region 140 is larger than a width W1 of the first n-type photoelectric conversion region 130.

In this way, the second n-type photoelectric conversion region 140 is larger in width than the first n-type photoelectric conversion region 130. Thus as shown in the potential drawing of FIG. 4A, long-wavelength input light can be efficiently absorbed by forming the photoelectric conversion region to a deep position. Further, by expanding the implantation cross-sectional area of the second n-type photoelectric conversion region 140, the potential profile of the second n-type photoelectric conversion region 140 is deeply formed and the substantial photoelectric conversion region is further expanded on the short-wavelength side, thereby increasing sensitivity on the short-wavelength side and the capacity of a photodiode.

The foregoing embodiments described examples in which the light receiving parts are formed on the p-type semiconductor substrates. By forming diffusion layers of opposite conductivity types, a light receiving part can be formed on an n-type semiconductor substrate.

1. A solid-state image device for obtaining an image by photoelectrically converting incident light in a light receiving part formed on a semiconductor substrate,
the light receiving part comprising:
a first semiconductor well of first conductivity type formed on an opposite side of the semiconductor substrate from an incident light receiving surface;
a second semiconductor well of the first conductivity type formed on a surface on the incident light receiving surface of the semiconductor substrate;
a charge storage region of second conductivity type formed between the first semiconductor well of the first conductivity type and the second semiconductor well of the first conductivity type, next to the first semiconductor well of the first conductivity type; and
a photoelectric conversion region formed next to the second semiconductor well of the first conductivity type and the charge storage region of the second conductivity type,
wherein the photoelectric conversion region is made up of a first photoelectric conversion region of the second conductivity type and a second photoelectric conversion region of the second conductivity type, and the photoelectric conversion region has a depth that enables photoelectric conversion of at least a half of incident light having a maximum wavelength in incident visible light, the depth being equivalent to a distance between the second semiconductor well of the first conductivity type and the charge storage region of the second conductivity type of the photoelectric conversion region.

2. The solid-state image device according to claim 1, wherein the photoelectric conversion region is at least 6 μm in depth.

3. The solid-state image device according to claim 1, wherein the first photoelectric conversion region of the second conductivity type has a lower impurity concentration than the second photoelectric conversion region of the second conductivity type.

4. The solid-state image device according to claim 3, wherein the second photoelectric conversion region of the second conductivity type has a larger implantation cross sectional area than the first photoelectric conversion region of the second conductivity type.

5. A method of manufacturing a solid-state image device, when forming the light receiving part of the solid-state image device according to claim 1,
the method comprising the steps of:
forming the first semiconductor well of the first conductivity type, the charge storage region of the second conductivity type, and the first photoelectric conversion region of the second conductivity type in the semiconductor substrate of the first conductivity type by ion implantation from a surface of an opposite side of the semiconductor substrate from the incident light receiving surface; and
forming the second photoelectric conversion region of the second conductivity type and the second semiconductor well of the first conductivity type in the semiconductor substrate of the first conductivity type by ion implantation from the surface on the incident light receiving surface.
